(19) United States
(12) Patent Application Publication
(10) Pub. No.: US 2018/0131049 A1
(43) Pub. Date: May 10, 2018

(54) APPARATUS AND METHOD FOR CHARGING VALVE REGULATED LEAD ACID BATTERIES

(71) Applicant: Smithville Labs, LLC, Smithville, TX (US)

(72) Inventors: Richard J Blanyer, Smithville, TX (US); Richard Goranflo, Smithville, TX (US); Phil Vinton, Grove, OK (US)

(73) Assignee: Smithville Labs, LLC, Smithville, TX (US)

(21) Appl. No.: 15/573,165

(22) PCT Filed: Jun. 10, 2016
(86) PCT No.: PCT/US16/36789

§ 371 Date: Nov. 10, 2017

Related U.S. Application Data
(60) Provisional application No. 62/175,370, filed on Jun. 14, 2015.
(60) Provisional application No. 62/239,192, filed on Oct. 8, 2015.
(60) Provisional application No. 62/287,342, filed on Jan. 26, 2016.

(51) Int. Cl. H01M 10/48; H02J 7/00; G01R 31/36

(52) U.S. Cl. CPC H01M 10/486; G01R 31/362; H02J 7/0024

(57) ABSTRACT

The present invention deals generally with an apparatus and method for charging valve regulated lead-acid (VRLA) batteries (modules) in series and series-parallel arrangements. More specifically, the present invention relates to an apparatus and method of individually, and very precisely, charging valve regulated lead-acid batteries in series and series-parallel arrangements so as to limit the water and electrolyte outgassing conventional bulk charging methods produce.

### CROSS-REFERENCE TO RELATED APPLICATIONS

This application takes benefit of U.S. Provisional Patent 62/175,370 filed Jun. 14, 2015; U.S. Provisional Patent 62/239,192 filed Oct. 8, 2015; and U.S. Provisional Patent 62/287,342 filed Jan. 26, 2016 and hereby incorporates all of them in their entirety by reference.

### FIELD OF THE INVENTION

The present invention deals generally with an apparatus and method for charging valve regulated lead-acid (VRLA) batteries (modules) in series and series-parallel arrangements. More specifically, the present invention relates to an apparatus and method of individually, and very precisely, charging valve regulated lead-acid batteries in series and series-parallel arrangements so as to limit the water and electrolyte outgassing conventional bulk charging methods produce.

### BACKGROUND OF THE INVENTION

The advent of asynchronous or periodic electrical generating systems, particularly wind generating systems, solar generating systems, and ocean generating systems, has necessitated the need for electrical storage systems capable of storing electricity as it is produced for use later when the facility is not generating power. Such facilities smooth, or balance, the output of the generating system such that it appears (within limits) to be a constant source of power. Many types of such systems have been developed, but large banks of conventional lead-acid batteries are among the most popular. For this purpose valve regulated lead-acid (VRLA) batteries are widely employed.

The main disadvantage of VRLA batteries in such applications relates to the fact the such batteries must be very precisely charged to limit the amount of water and electrolyte outgassing from any one particular battery. The reason for this is that any reduction in water concentration changes the internal chemical equilibrium of the battery thus altering its ability to accept a charge. Limiting water and electrolyte outgassing during recharge is relatively easy to accomplish when each battery is tied to its own bulk charging device, but with storage installations featuring hundreds or even thousands of such batteries this is impractical. Because of this, batteries in such applications are usually charged in series or series-parallel strings by a single bulk charger deriving power from the generating source. In these cases, water and electrolyte outgassing from at least a few cells is inevitable. As mentioned above, water and electrolyte outgassing alters a battery's ability to accept a charge, thus leading to situations in which affected batteries are over-charged by the bulk charger. This results in over-heating with an attendant risk of explosion and fire. The problem is compounded due to the fact that all of the batteries in a bank of VRLA batteries are slightly different. Whether due to minor variations in construction tolerance, age, number of charge/discharge cycles, and so on.

What is needed then is an apparatus and method of individually, and very precisely, charging batteries in an arrangement that does not solely use a bulk charger attached to individual batteries. This new apparatus and method would forego the above limitations associated with charging series or series-parallel strings of batteries using only a bulk charger.

One embodiment of the present invention solves this problem by providing an apparatus and method of individually, and very precisely, charging batteries in series or series-parallel strings that uses a conventional bulk charger to charge all the batteries to a predetermined first charge level below the level that might cause any battery in the string to outgas electrolyte and water and then completing (and maintaining) the charge to a second charge level with a small charger attached to each one (or a small group) of batteries.

Another embodiment of the present invention provides the advantage of combining the small charger referenced above with a network connectible battery status monitoring device. This small charger is connected to a central control computer by means of an RS-485 optical, versus electrical, network.

### SUMMARY OF THE INVENTION

The charge supply for each independent string of batteries that comprise a VRLA is set to about 2.9V times the number of cells in the VRLA. So, for example a 240V VRLA consisting of 20 12V batteries contains 20 times 6 (120 cells) so the main charge bulk supply will be set to 120 times about 2.9V (about 348V). The system is equipped with a System Control and Data Acquisition (SCADA) data acquisition system that monitors the voltage and temperature of each cell or module in the VRLA. The data acquisition system is interconnected using an RS-485 optical network. Charging is initiated after calculating the gassing voltage of each module based on its dynamic temperature. The initial charge rate is calculated based on the coldest module in the charging string. Charging is discontinued if any module temperature exceeds about 130° F. Further, electrolyte diffusion time must be allowed between each step of the charge sequence.

The present invention is directed towards a device that fully charges a series of series/parallel VRLA modules (cells or batteries) without disrupting the physical characteristics of the batteries that comprise the VRLA—most importantly eliminating spillage of electrolyte and outgassing while charging.

The present invention includes charging a string of VRLA modules that vary widely in temperature—Ranging from about 40° F. to about 120° F.

The present invention includes charging a string of VRLA modules wherein modules in the string have as much as 50% difference in capacity (volume).

The present invention includes charging and balancing the charge on a string of VRLA modules with as few charge cycles as possible. Normally this is thought to be one to two charging cycles.

The present invention compensates for changes in internal resistance within the VRLA modules due to the formation of corrosion barriers between the metallic grids and the PbO₂ active material that forms the positive electrodes of the batter(ies) by charging in current mode with unlimited voltage available to the VRLA module.

### BRIEF DESCRIPTION OF THE DRAWINGS

FIG. 1 is a diagram showing the electrical and optical connections present in one embodiment of the present invention.

FIG. 2 is a graph showing charging performance of a standard bank of batteries by a conventional bulk charging system.

FIG. 3 is a graph showing charging performance of a standard bank of batteries obtained using one embodiment of the present invention.

### DETAILED DESCRIPTION OF THE INVENTION

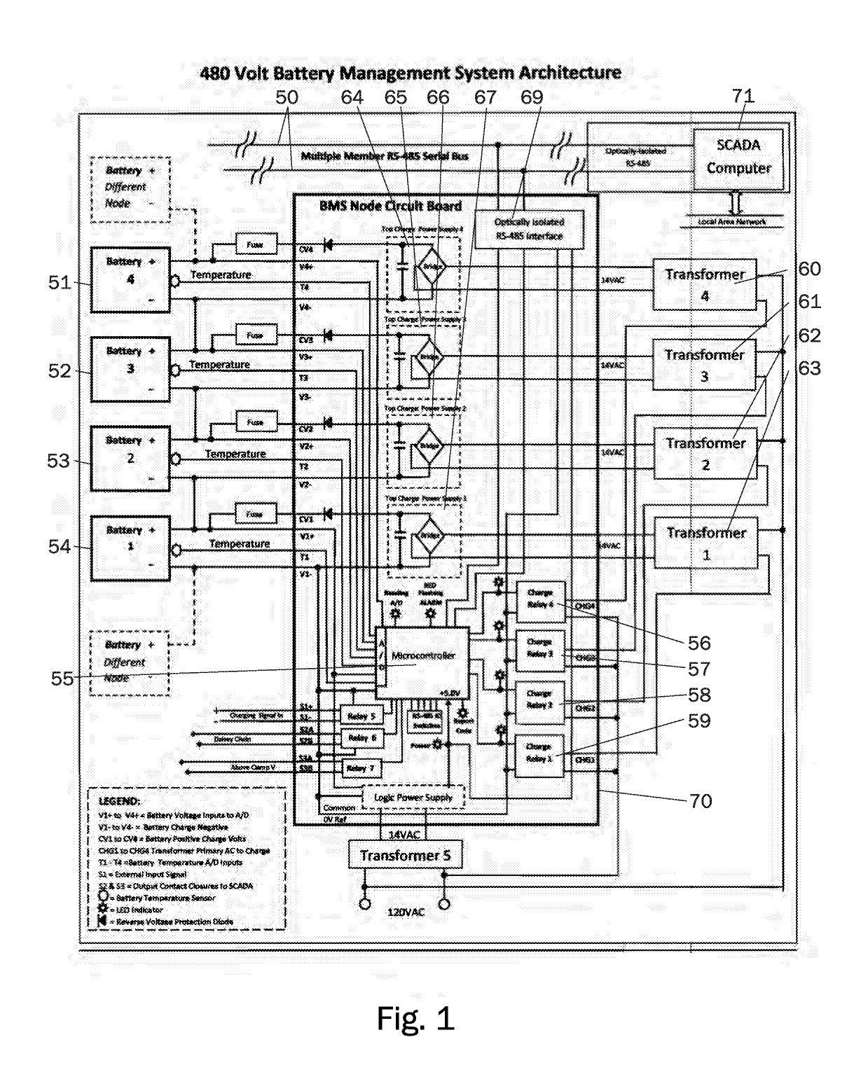

Referring now to FIG. 1, signaling and communication tasks in a battery management system of the present invention are handled on an optical network 50. In one embodiment of the present invention optical network 50 is an RS-485 serial bus. In one embodiment of the present invention four 12V DC batteries 51-54 are monitored by each monitoring microcontroller 55. Microcontroller 55 charges each battery 51-54 from an AC powered source. Simultaneously, microcontroller 55 monitors the temperature and voltage of each battery 51-54 while charging. Microcontroller 55 is in turn connected to SCADA computer 71 via optical network 50.

In one embodiment of the present invention, microcontroller 55 controls a charging relay 56-59 that supplies AC voltage to a transformer 60-63 and in turn to an AC-DC charging supply 64-67 associated with each battery 51-54. When DC voltage is supplied to battery 51-54, microcontroller 55 reads the internal temperature and voltage of battery 51-54 as it charges.

In one embodiment of the present invention, at least four VRLA batteries 51-54 are associated with each other for monitoring purposes. A Battery Management System Node circuit board (BMSNCB) 70 comprises part of the interface between four VRLA batteries 51-54 and the SCADA computer 71. BMSNCB 70 comprises: 1) The aforementioned microcontroller 55; 2) Four AC-DC charging supplies 64-67; 3) Four charge relays 56-59 capable of routing AC current to a particular AC-DC charging supply 64-67; and, 4) RS-485 interface 69 capable of coupling microcontroller 55 with SCADA computer 71 via optically isolated RS-485 serial bus 50. Each AC-DC charging supply 64-67 is wired to the input of a single battery 51-54. Each charge relay 56-59 is wired to transformer 60-63 mounted external to BMSNCB 70.

The system works in the following manner: 1) Microcontroller 55 monitors the voltage and the temperature of each of four attached batteries 51-54. 2) When appropriate, microcontroller 55 activates one of four charge relays 56-59. 3) Charge relay 56-59 then activates its connected transformer 60-63 supplying it with AC voltage. 4) Transformer 60-63 outputs a nominal 14V AC charge to AC-DC charging supply 64-67. 5) AC-DC charging supply 64-67 supplies a nominal 14V DC charge current to its attached battery 51-54. 6) Microcontroller 55 monitoring the temperature and voltage of battery 51-54 then deactivates (and activates) charge relay 56-59 associated with transformer 60-63 feeding AC-DC charging supply 64-67. 7) Simultaneously, microcontroller 55 asynchronously communicates via RS-485 serial bus 50 with its associated SCADA computer 71.

The system portrayed is just one of many implementations possible and other arrangements of components and functional parameters are permitted. For example, the charging voltage applied to the terminals of the battery is usually expected to be about 14V DC. But, this voltage would be appropriate for batteries with a basic charge of 12V DC. Obviously, other batteries of other voltages may be used and thus the charging voltage may vary widely.

Indeed, the system described functions on string voltages as high as 1500V DC. The described implementation of the device possesses nodes of four batteries. At a nominal 12V DC charge per battery a node thus sees only 48V DC. But these nodes are stacked one atop each other to scale to string voltages in excess of 1000V DC. The specification of the present patent teaches that none of the individual nodes is aware of voltages outside of the node, i.e. nodes are independent of one another and are optically isolated from each other and the SCADA computer.

By the same token, BMSNCB 70 and its related componentry charges different batteries 51-54 attached to it different amounts of time. For example, battery 51 may have a completely different battery charging sequence than battery 52, 53, and 54.

Similarly, transformers 60-63 are portrayed as being resident off of BMSNCB 70. This is not a design requirement. Nor is it a requirement that charge relays 56-59 be resident on BMSNCB 70. The physical arrangement of the various components comprising the system may obviously be changed.

It should be remembered that the implementation of the invention described in the present patent represents a “series connected string” implementation. The same architecture is deployable on “parallel connected strings (using isolation diodes)” and “individually connected and isolated” batteries.

The preceding sections disclose the structure of one embodiment of the present invention. The following sections disclose the phases one embodiment of the present invention uses to manage the charge of a string of VRLA batteries:

Phase 1—Bulk (Initial Charge)—Set the charge current to the VRLA battery manufacturer's maximum charge rate. Note that the VRLA maximum charge rate is reduced by 1.5% per each degree below 80° F. based on the coldest module in the string.

Phase 2—Ramp Phase—The initial bulk current is reduced by up to 50% (but not less than 33%) when any module in the string reaches its temperature compensated gassing voltage. This will usually be the hottest module in the string. The temperature compensated gassing voltage is determined by the manufacturer's calculations. For the Horizon battery it is calculated thusly:

(#cells×2.4167V)/((0.00167×80.6° F.)−temperature of the module in ° F.)

For example, at a module temperature of 80.6° F. the temperature compensated gassing voltage is 14.5V. The string bulk charge amperage is reduced by up to 50% (but not less than 33%) each time any module hits it's individually calculated temperature compensated gassing voltage. Obviously, Phase 2 operations must be conducted using modules equipped with temperature sensing equipment and calculated temperature compensated gassing voltage must be calculated in real-time for each module in the string.

Phase 3—Bulk String Charge End Phase—When the bulk string charge current has been reduced to approximately 5% on the modules C/3 rating, hold this charge current until any module in the string reaches its calculated temperature compensated gassing voltage whereupon the bulk string charger is shut off. For a Horizon 85 amp hour module (with a C/3 rating at the 3 hour discharge rate at 80.0° F.) this cutoff would be at 85 amp hours×0.05 or slightly less than 5 A.

Phase 4—Finish and Balance Phase—After bulk charging (described above) has been completed, one embodiment of the present invention accomplishes final module charging and string balancing. This embodiment of the present invention does this according to the following steps:

First, approximately 1 hour after Phase 3 Bulk String Charging End Phase has been completed, the Balancing Modules are energized. One embodiment of the present invention has one Balancing Module directly attached to each VRLA module. Each Balancing Module consists of a separate charging micro power supply comprising a transformer whose primary and secondary windings are impedance selected to the VRLA module's voltage (as described below). Operationally, current from this transformer is applied to the VRLA module to be balanced. The current from this transformer is full wave rectified and capacitor filtered as it is applied to the VRLA module. The transformer's primary and secondary windings are selected to saturate at a maximum secondary current that when rectified supplies approximately 3 A in the case of Horizon 12V×85 amp hour C/3 modules. Generally speaking, the transformer's primary and secondary windings are selected to saturate at a maximum secondary current of 3.5% of the VRLA modules C/3 rating and when not saturated allow the VRA module's DC voltage to reach approximately 2.9V per cell. This configuration provides a variable current with no limiting cell charging voltage and that current will start at approximately 3 A DC and will decrease to less than 1 A DC as the module battery's rising voltage “bucks” the micro-balancing power supply in the Balancing Module. Final charging and balancing occurs by allowing the VRLA module to reach full charge without gas or electrolyte being expelled though the module's safety pressure vent valve.

Next, each VRLA module is balance charged using the charger in the Balancing Module. Each VRLA is charged for an additional 2.5 to 3.0 minutes after it reaches its temperature compensated charge gassing voltage. The charge sequence is then terminated and approximately 1 hour later is allowed for electrolyte diffusion. This process is repeated about 4 to 5 times. This balance charging sequence is repeated generally on a daily basis but may only be required on a weekly or monthly basis depending on the duty cycle, health, or state of balance of the VRLA.

Phase 5—Keep Alive Cycles—After the string of VRLA modules is charged, it may be necessary to rebalance (as in Phase 4) one or more of the VRLA modules. This may be necessary in situations where one VRLA has a long open circuit stand or a self-discharge parasitically lowers the charge voltage of the VRLA. This may occur when external data acquisition equipment, or, a cell has dendrites (small shorts) forming. The keep alive cycle is triggered when a VRLA module falls to a predetermined voltage, and the charger in the Balancing Module is used to restore charge in the VRLA module to its temperature compensated gassing voltage. For most VRLA modules this keep alive trigger occurs when any module falls to 2.1V per cell at 80° F. The trigger voltage is calculated based on data from the VRLA's manufacturer.

Test Results

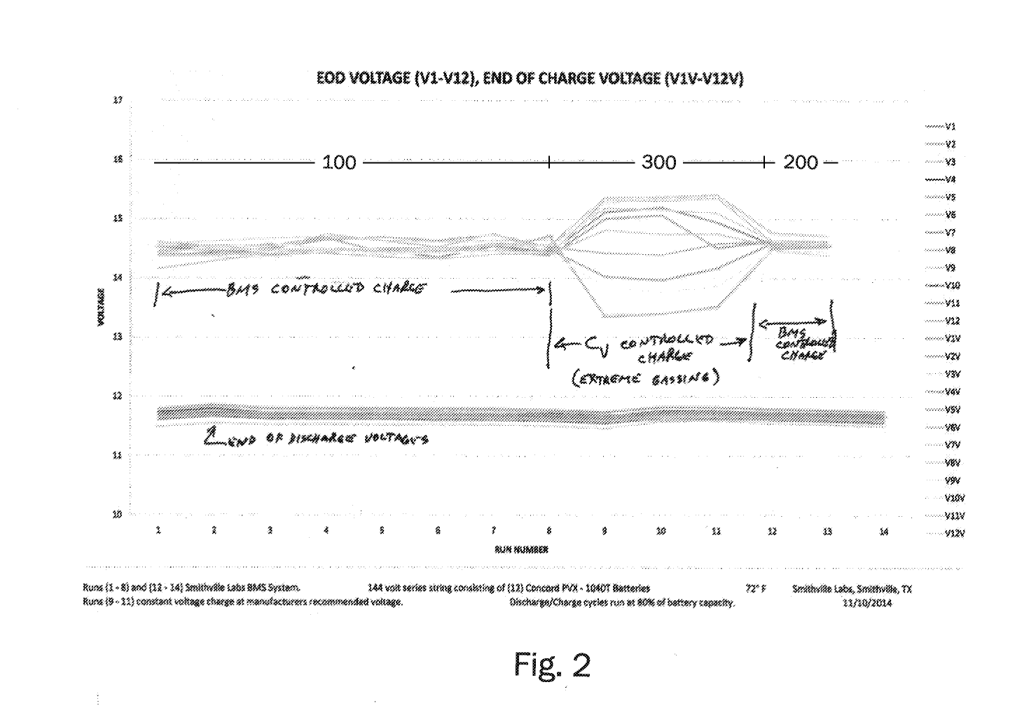

FIG. 2 shows data collected from a VRLA comprised of 12 12V×85 A/hour modules connected in a series string giving 144V. Charging cycles 1 through 8 (characterized as 100) and charging cycles 12 through 14 (characterized as 200) are charged using the disclosed invention. Cycles 9 through 11 (characterized as 300) are charged using a constant voltage set at the manufacturer's recommended charge voltage (14.4V×12 batteries or 172.8V). The peak charge voltage is controlled during charging cycles 1 through 8 (100) and 12 through 14 (200). The peak charge voltage is potentially high and variable depending on the battery during charging cycles 9 through 11 (300).

During charging cycles 9 through 11 (300) some of the batteries are violently overcharged. Also during charging cycles 9 through 11 (300) these overcharged batteries are expelling gas and electrolyte. This outgassing and electrolyte loss contributes to those batteries early failure.

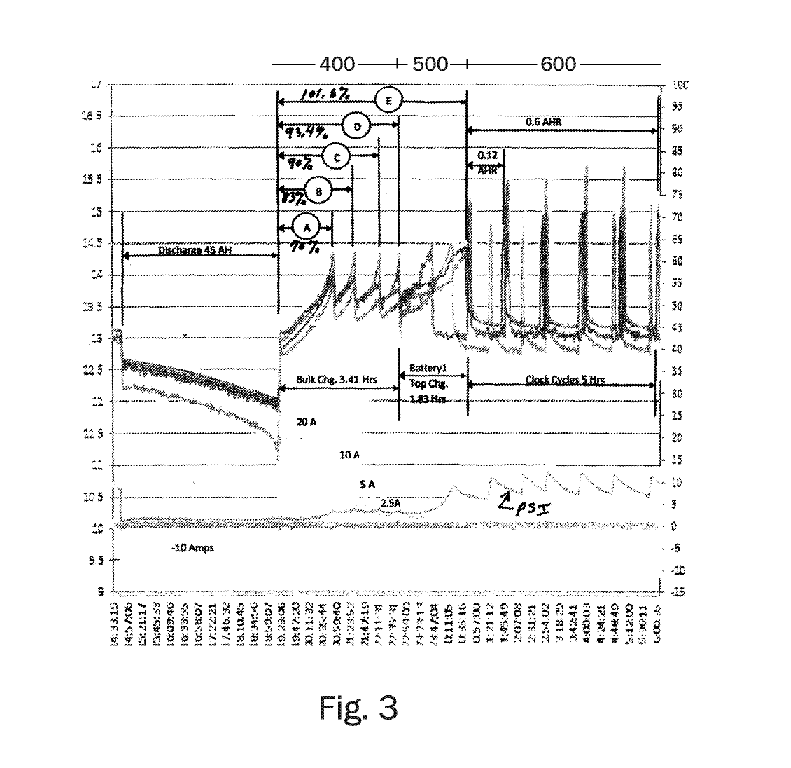

FIG. 3 depicts the results obtained charging a VRLA comprised of 4 12V×85 A/hour modules connected in a series string giving 48V using the disclosed invention. In this example the bulk recharge voltage is set to 17V per battery (17V×4 batteries or 68V) but the charger is operated in constant current mode (CI) only.

During the steps categorized as 400, the bulk charging current is cut in half for a period of time when any of the batteries reaches its temperature compensated gassing voltage. These timed and spaced current cuts allow time for diffusion within the electrolyte such that the specific gravity of the electrolyte is equivalent at all locations inside the battery. By this means each battery accepts more charging current without causing gassing and electrolyte loss.

During the step categorized as 500, the balancing phase occurs. Here, bulk charging current is turned off and each battery is charged independently by its micro-power balancing supply. Each micro-power balancing supply charges individual batteries independently.

During the step categorized as 600, clock cycles occur when each micro-power balancing supply independently charges its associated battery on an as needed basis to overcome dendrite formation and/or parasitic loads on each battery. The gas pressure in each battery stays below 1.5 psi (the pressure relief valve's setting for the battery). Thus, each battery never outgasses or discharges electrolyte.

1. An apparatus for maintaining the charging of valve regulated lead-acid (VRLA) batteries wherein said VRLA batteries operate exclusively at temperatures less than about 130° F. comprising:
a. at least one bulk charger capable of charging a multiplicity of VRLA batteries;
b. at least one SCADA computer capable of controlling the at least one bulk charger;
c. at least one Battery Management System Node circuit board capable of independently charging at least one associated battery; and
d. an optical interface network connecting the at least one Battery Management System Node circuit board with the at least one SCADA computer
wherein said apparatus eliminates the outgassing of water and electrolyte from the batteries when charging the batteries, and
wherein each VRLA battery will be recharged in current mode without voltage limits on the charger power supply.

2. An apparatus of claim 1 capable of monitoring the voltage and temperature of each of the multiplicity of batteries.

3. An apparatus of claim 1 capable of generating a bulk charging voltage applied to the terminals of each of the multiplicity of batteries of about 14V DC.

4. An apparatus of claim 1 capable of charging each of the multiplicity of batteries a different amount of time.

5. An apparatus for maintaining the charge level on VRLA batteries comprising:
a. at least one bulk charger capable of charging a multiplicity of VRLA batteries; and
b. a multiplicity of Battery Management System Nodes each capable of charging at least one VRLA battery
wherein said apparatus eliminates the outgassing of water and electrolyte from the batteries when charging the batteries, and
wherein each VRLA battery will be recharged in current mode without voltage limits on the charger power supply.

6. An apparatus of claim 5 capable of maintaining the charge level on VRLA batteries such that no gas is expelled from the one or more VRLA batteries.

7. An apparatus of claim 5 capable of maintaining the charge level of VRLA batteries such that no electrolyte is expelled from the one or more VRLA batteries.

8. An apparatus of claim 5 further comprising a Battery Management System Nodes further comprising a transformer whose primary and secondary windings are impedance matched to the VRLA such that at saturation it can deliver about 3.5% of the VRLA module's C/3 rating.

9. An apparatus of claim 5 further comprising a Battery Management System Nodes further comprising a transformer whose primary and secondary windings are impedance matched to the VRLA such that at saturation it can deliver as much as about 3V/cell thus reducing its current output below the module's C/50 rating as the voltage rises and bucks the micro-power balancing charger output voltage.

10. An apparatus of claim 5 wherein all of the VRLA batteries will be brought to a full charge at any module temperature between about 40.0° F. and about 120.0° F.

11. An apparatus of claim 5 wherein all of the VRLA batteries will be charged with a maximum overcharge of 1.0% to 3.0% above the VRLA battery's previous maximum discharge ampere hours.

12. An apparatus of claim 5 wherein each VRLA battery will be completely recharged and will end its charge cycle with less than about 1.5 psi within the VRLA battery.

13. (canceled)

14. An apparatus of claim 5 wherein each VRLA battery in the string may be different in module capacity by as much as 50%.

15. An apparatus of claim 5 wherein at least one VRLA battery may be new and unused.

16. An apparatus of claim 5 wherein at least one VRLA battery may be used.
